(19) United States
(12) Patent Application Publication
(10) Pub. No.: US 2025/0393200 A1
(43) Pub. Date: Dec. 25, 2025

(54) Semiconductor Device and Method for manufacturing thereof

(71) Applicant: Fujian Jinhua Integrated Circuit Co., Ltd., Jinjiang (CN)

(72) Inventor: LI-WEI FENG, Jinjiang (CN)

(73) Assignee: Fujian Jinhua Integrated Circuit Co., Ltd., Jinjiang (CN)

(21) Appl. No.: 19/015,440

(22) Filed: Jan. 9, 2025

(30) Foreign Application Priority Data
Jun. 25, 2024 (CN) 202410832178.6
Jun. 25, 2024 (CN) 202421470751.5

(51) Int. Cl. H10B 12/00

(52) U.S. Cl. CPC H10B 12/485; H10B 12/02

(57) ABSTRACT

Disclosed are a semiconductor device and a method for manufacturing thereof. The semiconductor device includes: a substrate, including a plurality of bit lines and gate structures; a first dielectric layer, located between adjacent gate structures; a plurality of connectors, located in the first dielectric layer and connected to the substrate; a plurality of contact structures, located between adjacent bit lines; a plurality of capacitor structures, located on the contact structures; a hard mask layer, covering the top surfaces of the connectors; and a second dielectric layer, including a first portion located above the hard mask layer and a second portion located above the contact structures, the vertexes of the first portion and the second portion of the second dielectric layer being at different horizontal heights.

### TECHNICAL FIELD

The present disclosure relates to the technical field of semiconductors, and in particular to a semiconductor device and a method for manufacturing thereof.

### BACKGROUND

Dynamic random access memory (DRAM) is a transitory memory. A DRAM apparatus generally include a memory region composed of an array of memory cells, and a peripheral region composed of a control circuit. The control circuit in the peripheral region may address each memory cell in the memory region by means of multiple columns of word lines and multiple rows of bit lines traversing the memory region, and is electrically connected to each memory cell, so as to read, write or erase data.

In current semiconductor manufacturing, semiconductor devices of a memory cell and a peripheral circuit are simultaneously formed using the same manufacturing process. The manufacturing process generally includes a patterning process. How to ensure the performance of devices while forming a memory cell and a peripheral circuit using multiple processes such as the patterning process is a problem to be solved urgently in the related art.

### SUMMARY

Embodiments of the present disclosure provide a semiconductor device and a method for manufacturing thereof.

According to one aspect of the present disclosure, a semiconductor device is provided, including: a substrate, including a plurality of bit lines and gate structures; a first dielectric layer, located between adjacent gate structures; a plurality of connectors, located in the first dielectric layer and connected to the substrate; a plurality of contact structures, located between adjacent bit lines; a plurality of capacitor structures, located on the contact structures; a hard mask layer, covering the top surfaces of the connectors; and a second dielectric layer, including a first portion located above the hard mask layer and a second portion located above the contact structures, the vertexes of the first portion and the second portion of the second dielectric layer being at different horizontal heights.

According to another aspect of the present disclosure, a semiconductor device is provided, including: a substrate, including a plurality of bit lines and gate structures; a first dielectric layer, located between adjacent gate structures; a plurality of connectors, located in the first dielectric layer and connected to the substrate; a plurality of contact structures, located between adjacent bit lines; a plurality of capacitor structures, located on the contact structures; a hard mask layer, covering the top surfaces of the connectors; and a second dielectric layer, covering the hard mask layer and being directly contact the top surfaces of the connectors and the side walls of the capacitor structures.

In some embodiments, the vertex of the first portion of the second dielectric layer is higher than the vertex of the second portion.

In some embodiments, the vertex of the hard mask layer is higher than the vertex of the second portion of the second dielectric layer.

In some embodiments, the hard mask layer includes a first sub-mask covering the connectors and a second sub-mask covering the contact structures, and the vertex of the first sub-mask is higher than the vertex of the second sub-mask.

In some embodiments, the hard mask layer is completely isolated from the top surfaces of the contact structures.

In some embodiments, the semiconductor device further includes a third dielectric layer located above the gate structures and between adjacent connectors, the vertex of the third dielectric layer being lower than the vertex of the hard mask layer.

In some embodiments, the hard mask layer is directly contact the top surfaces of the connectors and the side walls of the capacitor structures.

According to another aspect of the present disclosure, a method for manufacturing a semiconductor device is further provided, including: a substrate is provided, the substrate including a plurality of bit lines and gate structures; and a first dielectric layer is formed between adjacent gate structures; a plurality of connectors located in the first dielectric layer are formed; a plurality of contact structures located between adjacent bit lines are formed; a hard mask layer covering the top surfaces of the connectors is formed; and a second dielectric layer and capacitor structures are formed, the capacitor structures being located on the contact structures, and the second dielectric layer covering the hard mask layer, wherein the second dielectric layer includes a first portion located above the hard mask layer and a second portion located above the contact structures, and the vertexes of the first portion and the second portion of the second dielectric layer are at different horizontal heights.

In some embodiments, the method further includes: a conductive material covering the bit lines and the gate structures is formed; a patterned hard mask is formed on the surface of the conductive material; the conductive material is partially removed to form electric connectors and the contact structures; and the patterned hard mask located on the contact structures are completely removed, so as to form a hard mask layer covering the top surfaces of the connectors.

In some embodiments, the method further includes: a conductive material covering the bit lines and the gate structures is formed; a patterned hard mask is formed on the surface of the conductive material; the conductive material is partially removed to form electric connectors and the contact structures; and the patterned hard mask is partially removed to form a first sub-mask covering the connectors and a second sub-mask covering the contact structures, the vertex of the first sub-mask being higher than the vertex of the second sub-mask.

In some embodiments, the method further includes: a third dielectric layer is formed, such that the third dielectric layer is located above the gate structures and between adjacent connectors.

### BRIEF DESCRIPTION OF THE DRAWINGS

The drawings, constituting a part of some embodiments of the present disclosure, are used for providing further understanding of some embodiments of the present disclosure, and the illustrative embodiments of the present disclosure and illustrations thereof are used to explain the present disclosure, rather than constitute inappropriate limitation on the present disclosure. In the drawings:

FIG. 1 is a schematic partial sectional diagram of a semiconductor device provided according to embodiments of the present disclosure;

FIG. 2 is a schematic sectional diagram of a first connector and a second connector in a semiconductor device provided according to embodiments of the present disclosure;

FIG. 3 is a schematic partial sectional diagram of another semiconductor device provided according to embodiments of the present disclosure;

FIG. 4 is a process flowchart of a method for manufacturing a semiconductor device provided according to embodiments of the present disclosure;

FIG. 5 is a schematic partial sectional diagram after bit lines and gate structures are formed on the substrate in a method for manufacturing a semiconductor device provided according to embodiments of the present disclosure;

FIG. 6 is a schematic partial sectional diagram after contact holes are formed in the gate structures shown in FIG. 5;

FIG. 7 is a schematic partial sectional diagram after a conductive material and a mask material are deposited on the substrate shown in FIG. 6;

FIG. 8 is a schematic partial sectional diagram after connectors and a hard mask layer are formed by etching the mask material shown in FIG. 7;

FIG. 9 is a schematic partial sectional diagram after the connectors shown in FIG. 8 are covered with a dielectric material;

FIG. 10 is a schematic partial sectional diagram after the dielectric material shown in FIG. 9 is etched; and

FIG. 11 is a schematic partial sectional diagram after a second dielectric layer and a third dielectric layer are formed by the dielectric material shown in FIG. 10.

### DETAILED DESCRIPTION OF THE EMBODIMENTS

It is to be noted that embodiments in the present disclosure and features in the embodiments may be combined with one another without conflicts. Hereinafter, embodiments of the present disclosure are described in detail with reference to the accompanying drawings and in combination with the embodiments.

In order to enable a person skilled in the art to understand the solutions of the present disclosure better, hereinafter, the technical solutions in the embodiments of the present disclosure will be described clearly and thoroughly with reference to the accompanying drawings of embodiments of the present disclosure. Obviously, the embodiments as described are only some of the embodiments of the present disclosure, rather than all the embodiments. All other embodiments obtained by a person of ordinary skill in the art on the basis of the embodiments in the present disclosure without involving any inventive effort shall all fall within the scope of protection of the present disclosure.

It should be noted that the terms “first”, “second”, etc. in the description, claims, and accompanying drawings of the present disclosure are used to distinguish similar objects, and are not necessarily used to describe a specific sequence or order. It should be understood that the data so used may be interchanged where appropriate, so that embodiments of the present disclosure described herein can be implemented in sequences other than those illustrated or described herein. In addition, the terms “include” and “have” and any variations thereof are intended to cover a non-exclusive inclusion, for example, a process, method, system, product or device that includes a series of steps or units is not necessarily limited to those steps or units that are clearly listed, but may include other steps or units that are not clearly listed or inherent to such process, method, product or device.

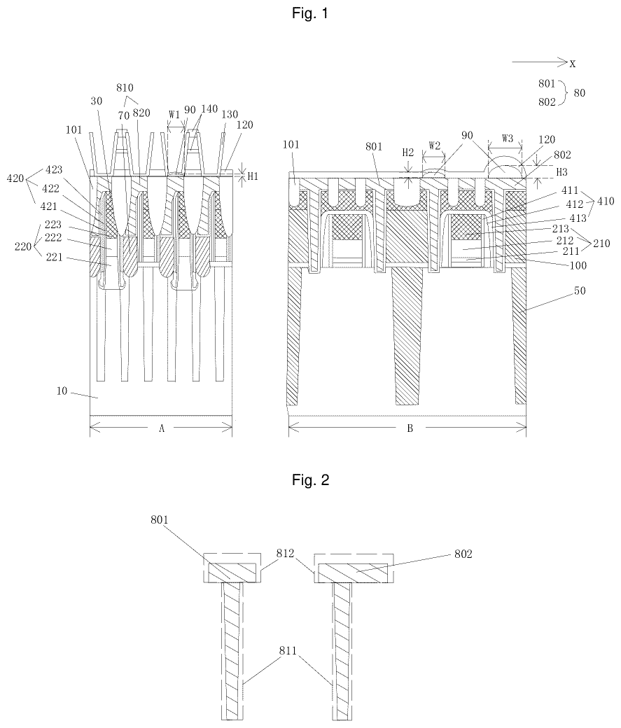

According to embodiments of the present disclosure, a semiconductor device is provided. FIG. 1 is a schematic structural diagram of a semiconductor device according to embodiments of the present disclosure.

As shown in FIG. 1, the semiconductor device includes a substrate 10, a plurality of bit lines 220, a plurality of gate structures 210, a first dielectric layer 100, a plurality of connectors 80, a plurality of contact structures 810, a plurality of capacitor structures 130, a hard mask layer 90 and a second dielectric layer 120, wherein the substrate 10 includes a cell region and a peripheral region; the plurality of bit lines 220 are located on the cell region; the plurality of gate structures 210 are located on the peripheral region; the first dielectric layer 100 is located between adjacent gate structures 210; the plurality of connectors 80 are located in the first dielectric layer 100 and are connected to the substrate; the plurality of contact structures 810 are located between adjacent bit lines 220; the plurality of capacitor structures 130 are located on the contact structures 810; the hard mask layer 90 covers the top surfaces of the connectors; and the second dielectric layer 120 includes a first portion located above the hard mask layer 90 and a second portion located above the contact structures 810, the vertexes of the first portion and the second portion of the second dielectric layer 120 being at different horizontal heights.

In the semiconductor device according to embodiments of the present disclosure, as shown in FIG. 1, Since the hard mask layer 90 covers the top surfaces of the connectors 80, and the second dielectric layer includes a first portion located above the hard mask layer 90 and a second portion located above the contact structures, the vertexes of the first portion and the second portion of the second dielectric layer 120 being at different horizontal heights, the hard mask layer 90 is formed by a remaining hard mask material during formation of the connectors 80. During formation of the connectors 80, the hard mask material is deposited in both the memory region and the peripheral region, grooves are formed in the peripheral region by means of a patterning process and an etching process so as to separate a plurality of connectors 80, and the memory region is also synchronously etched to form grooves. Due to the difference in materials, the depth of the grooves formed in the memory region may be greater than the depth of the grooves in the peripheral region, and if the depth of the grooves in the memory region is relatively large, a short circuit may occur to the bit lines 220 due to over-etching. In the embodiments of the present disclosure, by remaining a hard mask material on the surface of a second connector 802, it is possible to prevent grooves formed by etching in a memory region from being too deep, thereby avoiding the risk of over-etching, and improving the reliability of devices.

Furthermore, the hard mask layer 90 may be formed by remaining a hard mask material on the top surfaces of the connectors 80 while forming the contact structures 810 and the connectors 80 using a patterning process in the manufacturing process of the semiconductor device, so that additional process steps are not required, thereby achieving the technical effect of improving the performance of the semiconductor device without increasing the process time and process costs.

In the semiconductor device according to embodiments of the present disclosure, as shown in FIG. 1, the semiconductor structure includes a substrate 10, and a peripheral region B and a memory region A are defined on the substrate 10.

Shallow trench isolation (STI) structures 50 may be formed in the substrate 10, so as to define a plurality of active regions of memory cells in the memory region A of the substrate 10 and define a plurality of active regions of the semiconductor device in the peripheral region B of the substrate 10. The substrate 10 may be a silicon substrate, a silicon-containing substrate, a silicon-on-insulator (SOI) substrate, or other semiconductor substrates, which is not specifically limited in the embodiments of the present disclosure.

The peripheral region B may be provided with a peripheral circuit for controlling the operation and input/output of the memory cells in the memory region A. For example, a driver, a buffer, an amplifier, and a decoder may be provided. The peripheral region B can further include a circuit for repairing an anomalous memory cell, such as a fuse circuit, which is not specifically limited in the embodiments of the present disclosure. The memory region A may be provided with an array of memory cells, such as DRAM cells. According to embodiments of the present disclosure, the semiconductor device of the peripheral circuit in the peripheral region B and the DRAM cells in the memory region A are manufactured on the substrate 10 using the same manufacturing process.

In the semiconductor device according to embodiments of the present disclosure, as shown in FIG. 1, the plurality of bit lines 220 may be arranged at intervals on the memory region A along the x direction, the plurality of gate structures 210 may be arranged at intervals on the peripheral region B along the x direction, and the plurality of gate structures 210 formed on the peripheral region B and the plurality of bit lines 220 formed on the memory region A may be manufactured by means of the same process steps. Exemplarily, a semiconductor material layer, a metal material layer and a hard mask material layer are sequentially formed on the peripheral region B and the memory region A of the substrate 10, and a patterning process is performed on the hard mask material layer to obtain a patterned mask, and then the patterned mask is used as a mask to sequentially etch the metal material layer and the semiconductor material layer, so as to transfer the pattern of the patterned hard mask to the semiconductor material layer, thereby obtaining the gate structures 210 and the bit lines 220.

The gate structures 210 may respectively include a first semiconductor layer 211, a first metal layer 212 and a first patterned mask 213 which are sequentially stacked in a direction away from the substrate 10. The bit lines 220 may respectively include a second semiconductor layer 221, a second metal layer 222 and a second patterned mask 223 which are sequentially stacked in a direction away from the substrate 10. The materials of the first semiconductor layer 211 and the second semiconductor layer 221 may include polysilicon; the materials of the first metal layer 212 and the second metal layer 222 may include aluminum (Al), tungsten (W), copper (Cu), titanium (Ti), titanium aluminum alloy (TiAl) and other low-resistivity metal materials; and the materials of the first patterned mask 213 and the second patterned mask 223 may include any one or more of silicon nitride (SiN), silicon oxynitride (SiON) and silicon carbon nitride (SiCN), and may also include other dielectric materials. The embodiments of the present disclosure do not specifically limit the types of the described materials.

It should be noted that a gate oxide layer (not shown in the figure) may be further provided between the substrate 10 and the first semiconductor layers 211 of the gate structures 210, and the material of the gate oxide layer may be silicon oxide (SiO₂).

In the semiconductor device according to embodiments of the present disclosure, as shown in FIG. 1, the first dielectric layer 100 is located between adjacent gate structures 210. The semiconductor device according to embodiments of the present disclosure may further include a barrier layer 30 located on the gate structures 210 and the first dielectric layer 100. The materials of the first dielectric layer 100 and the blocking layer 30 may include any one or more of silicon oxide (SiO₂), silicon nitride (SiN), silicon oxynitride (SiON) and silicon carbon nitride (SiCN), and may further include other types of dielectric materials, which are not specifically limited in the embodiments of the present disclosure.

As shown in FIG. 1, the semiconductor device according to embodiments of the present disclosure may further include a first side wall 410 located at two sides of the gate structure 210. Exemplarily, the first side wall 410 includes a first insulating layer 411, a second insulating layer 412 and a third insulating layer 413 sequentially covering the side wall of the gate structure 210 from inside to outside.

As shown in FIG. 1, the semiconductor device according to embodiments of the present disclosure may further include a second side wall 420 located at two sides of the bit line 220. Exemplarily, the second side wall 420 includes a fourth insulating layer 421, a fifth insulating layer 422 and a sixth insulating layer 423 sequentially covering the side walls of the bit line 220 and the barrier layer 30 from inside to outside.

The first side wall 410 and the second side wall 420 may be manufactured using the same process steps, and the materials of the insulating layers in the first side wall 410 and the second side wall 420 may be a conventional insulating material in the related art, such as silicon oxide (SiO₂), which is not specifically limited in the embodiments of the present disclosure.

In the semiconductor device according to embodiments of the present disclosure, as shown in FIG. 2, the connectors 80 may include a plurality of first connectors 801 and at least one second connector 802. Each connector 80 includes a first connecting portion 811 and a second connecting portion 812. The first connecting portion 811 is located between at least one gate structure 210 and an adjacent first dielectric layer 100, the second connecting portion 812 is located at the side of the first connecting portion 811 facing away from the substrate 10, and the side surface of the second connecting portion 812 facing away from the first connecting portion 811 in the second connector 802 is a first surface. The material of the connectors 80 may include metal, such as tungsten (W).

In the semiconductor device according to embodiments of the present disclosure, as shown in FIG. 1, the plurality of contact structures 810 are located between adjacent bit lines 220. The contact structure 810 includes a semiconductor structure 70 located between adjacent bit lines 220 and a contact pad 820 located on the semiconductor structure 70. The material of the semiconductor structure 70 may include polysilicon, and the material of the contact pad 820 may include metal, such as tungsten (W). Exemplarily, the semiconductor structure 70 is filled in the bottom of a storage node contact opening 620 between adjacent bit lines 220; and one part of the contact pad 820 is filled above the semiconductor structure 70, and the other part of the contact pad 820 is located outside the storage node contact opening and covers a part of the top surface of a bit line.

In the semiconductor device according to embodiments of the present disclosure, as shown in FIG. 1, the second dielectric layer 120 includes a first portion located above the hard mask layer 90 and a second portion located above the contact structures 810. The vertexes of the first portion and the second portion of the second dielectric layer 120 are at different horizontal heights. The hard mask layer 90 may be formed by remaining a hard mask material on the top surfaces of the connectors while removing the hard mask material on the top surfaces of the contact structures 810 using a patterning process in the manufacturing process of the semiconductor device. The material of the second dielectric layer 120 may include any one or more of silicon oxide (SiO₂), silicon nitride (SiN), silicon oxynitride (SiON) and silicon carbon nitride (SiCN), and may further include other types of dielectric materials, which are not specifically limited in the embodiments of the present disclosure.

In some optional embodiments of the present disclosure, as shown in FIG. 1, the second dielectric layer 120 includes a first portion located above the hard mask layer and a second portion located above the contact structures 810, the vertex of the first portion being higher than the vertex of the second portion. A hard mask material is deposited in both the memory region A and the peripheral region B, and a patterning process and an etching process are sequentially performed, so as to form grooves in the peripheral region B, a plurality of connectors 80 are separated by means of the grooves, and the memory region A is also synchronously etched to form grooves. Due to the difference in materials, the depth of the grooves formed in the memory region A may be greater than the depth of the grooves in the peripheral region B, and if the depth of the grooves in the memory region A is relatively large, a short circuit may occur to the bit lines 220 due to over-etching. In the embodiments of the present disclosure, by remaining a hard mask material on the surface of the second connector 802, it is possible to prevent the grooves formed by etching in the memory region A from being too deep, thereby avoiding the risk of over-etching, and improving the reliability of devices.

Exemplarily, as shown in FIG. 1, the plurality of connectors 80 include first connectors 801 and a second connector 802, and the size of the top surface of the first connector 801 is smaller than the size of the top surface of the second connector 802. The hard mask layer 90 is located on the top surfaces of the first connectors 801, the size of the bottom surface of the hard mask layer 90 contact the top surface of the second connector 802 is W3, and the height of the hard mask layer 90 is H3. Specifically, the hard mask layer 90 is formed by at least remaining a hard mask material on the top surface of the second connector 802 while forming the contact structures 810 and the connectors 80 using a patterning process in the manufacturing process of the semiconductor device. In this case, the hard mask material on the top surface of the second connector 802 and the top surfaces of the contact structures 810 can be removed.

In another example, as shown in FIG. 1, the hard mask layer 90 is also located on the top surface of a contact pad 820 in at least one contact structure 810, the size of the bottom surface of the hard mask layer 90 contact the top surface of the contact pad 820 is W1, and the height of the hard mask layer 90 is H1. Specifically, in the manufacturing process of the semiconductor device, while the contact structures 810 and the connectors 80 are formed using the patterning process, the hard mask material is remained on both the top surface of the second connector 802 and the top surface of at least one contact structure 810, and the hard mask material on the top surface of the second connector 802 and the top surfaces of the remaining contact structures 810 are removed.

In another example, as shown in FIG. 1, the hard mask layer 90 is also located on the top surface of the second connector 802, the size of the bottom surface of the hard mask layer 90 contact the top surface of the first connector 801 is W2, and the height of the hard mask layer 90 is H2. In the manufacturing process of the semiconductor device, while the contact structures 810 and the connectors 80 are formed using the patterning process, in addition to remaining of the hard mask material on the top surfaces of the first connectors 801 and the top surface of at least one contact structure 810, the hard mask material is also remained on the top surface of at least one second connector 802, and the remaining hard mask material forms the hard mask layer 90. Since the size of the top surface of the second connector 802 is greater than the size of the top surface of the first connector 801, the size of the hard mask layer 90 located on the top surface of the first connector 801 is greater than that of the hard mask layer 90 located on the top surface of the second connector 802. The size of the bottom surface of the hard mask layer 90 contact the top surface of the first connector 801 is greater than the size of the bottom surface of the hard mask layer 90 contact the top surface of the second connector 802, and the height of the hard mask layer 90 on the top surface of the first connector 801 is also greater than the height of the hard mask layer 90 on the top surface of the second connector 802.

In some optional embodiments of the present disclosure, as shown in FIG. 1, the hard mask layer 90 includes a first sub-mask covering the connectors 80 and a second sub-mask covering the contact structures 810, and the vertex of the first sub-mask is higher than the vertex of the second sub-mask. The first sub-mask is disposed on the top surface of at least one connector 80, and the second sub-mask is disposed on the top surface of at least one contact structure 810. The first sub-mask and the second sub-mask may be formed by remaining a hard mask material on the top surfaces of the connectors 80 while forming the contact structures 810 and the connectors 80 using a patterning process in the manufacturing process of the semiconductor device.

In some optional embodiments of the present disclosure, the hard mask layer is completely isolated from the top surfaces of the contact structures. In this case, the hard mask layer is formed by remaining a hard mask material on the top surface of at least one connector while removing the hard mask material on the top surfaces of the contact structures using a patterning process in the manufacturing process of the semiconductor device.

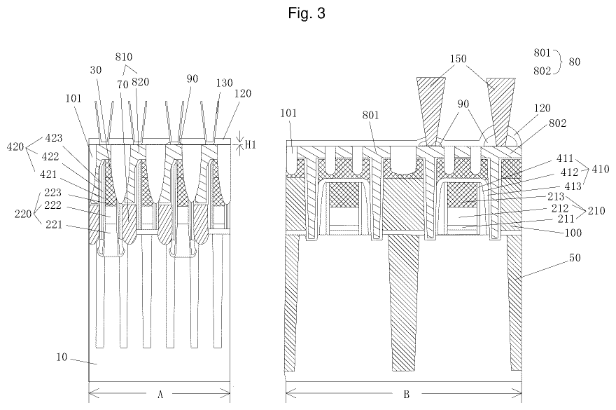

As shown in FIG. 3, the hard mask layer 90 may also be directly contact the top surfaces of the contact structures 810 and the side walls of the capacitor structures 130, and after wires 150 are connected above the connectors 80 (the first connector 801 and the second connector 802), the hard mask layer 90 is contact the side walls of the wires 150.

In the semiconductor device according to embodiments of the present disclosure, as shown in FIGS. 1 and 3, a plurality of capacitor structures 130 are located on the contact structures 810, and each capacitor structure 130 is connected to at least one adjacent capacitor structure 130 by means of a support layer 140.

The plurality of capacitor structures 130 are arranged at intervals above the substrate 10, and are connected to the contact pads 820 in the contact structures 810 in one-to-one correspondence.

According to embodiments of the present disclosure, a semiconductor device is further provided. FIG. 3 is a schematic structural diagram of a semiconductor device according to embodiments of the present disclosure.

As shown in FIG. 3, the semiconductor device includes a substrate 10, a plurality of bit lines 220, a plurality of gate structures 210, a first dielectric layer 100, a plurality of connectors 80, a plurality of contact structures 810, a plurality of capacitor structures 130, a hard mask layer 90 and a second dielectric layer 120, wherein the substrate 10 includes a cell region and a peripheral region; the plurality of bit lines 220 are located on the cell region; the plurality of gate structures 210 are located on the peripheral region; the first dielectric layer 100 is located between adjacent gate structures 210; the plurality of connectors 80 are located in the first dielectric layer 100 and are connected to the substrate; the plurality of contact structures 810 are located between adjacent bit lines 220; the plurality of capacitor structures 130 are located on the contact structures 810; the hard mask layer 90 covers the top surfaces of the connectors; and the second dielectric layer 120 covers the hard mask layer 90 and is directly contact the top surfaces of the connectors 80 and the side walls of the capacitor structures 130.

In the semiconductor device according to embodiments of the present disclosure, as shown in FIG. 3, the hard mask layer 90 may be formed by remaining a hard mask material on the top surfaces of the connectors while removing the hard mask material on the top surfaces of the contact structures 810 using a patterning process in the manufacturing process of the semiconductor device. Specifically, the hard mask material is deposited in both the memory region A and the peripheral region B, and a patterning process and an etching process are sequentially performed, so as to form grooves in the peripheral region B to separate a plurality of connectors 80, and the memory region A is also synchronously etched to form grooves. Due to the difference in materials, the depth of the grooves formed in the memory region A may be greater than the depth of the grooves in the peripheral region B, and if the depth of the grooves in the memory region A is relatively large, a short circuit may occur to the bit lines 220 due to over-etching. In the embodiments of the present disclosure, by remaining a hard mask material on the surface of the second connector 802, it is possible to prevent grooves formed by etching in the memory region A from being too deep, thereby avoiding the risk of over-etching, and improving the reliability of devices.

In the semiconductor device according to embodiments of the present disclosure, the positional relationship and the materials of the substrate 10, the bit lines 220, the gate structures 210, the first dielectric layer 100, the connectors 80, the contact structures 810, the capacitor structures 130 and the hard mask layer 90 may be the same as those of the semiconductor device provided in the embodiments above, and will not be repeated in the embodiments of the present disclosure.

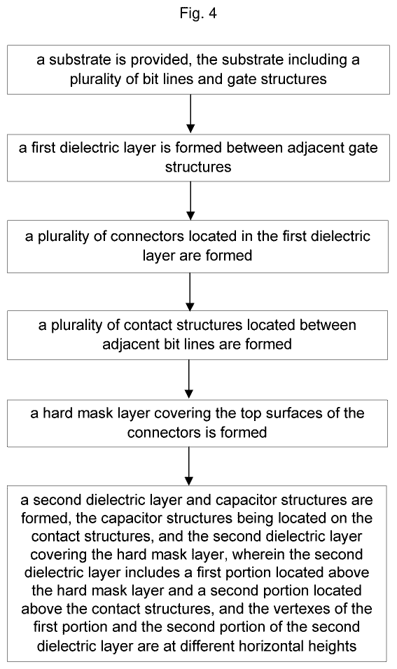

According to embodiments of the present disclosure, a method for manufacturing a semiconductor device is further provided. FIG. 4 is a process flowchart of a method for manufacturing a semiconductor device provided according to embodiments of the present disclosure.

As shown in FIGS. 4 to 11, the method for manufacturing a semiconductor device includes the following steps:
a substrate 10 is provided, the substrate 10 including a cell region and a peripheral region;
a plurality of bit lines 220 are formed on the cell region, a plurality of gate structures 210 are formed on the peripheral region, and a first dielectric layer 100 is formed between adjacent gate structures 210;
a plurality of connectors 80 located in the first dielectric layer 100 are formed;
a plurality of contact structures 810 located between adjacent bit lines 220 are formed;
a hard mask layer 90 covering the top surfaces of the connectors 80 is formed; and
a second dielectric layer 120 and capacitor structures 130 are formed, the capacitor structures 130 being located on the contact structures 810, and the second dielectric layer 120 covering the hard mask layer 90, wherein the second dielectric layer 120 includes a first portion located above the hard mask layer 90 and a second portion located above the contact structures 810, and the vertexes of the first portion and the second portion of the second dielectric layer 120 are at different horizontal heights.

In the method for manufacturing a semiconductor device according to embodiments of the present disclosure, since the hard mask layer 90 covering the top surfaces of the connectors 80 is formed, and the second dielectric layer includes a first portion located above the hard mask layer 90 and a second portion located above the contact structures, the vertexes of the first portion and the second portion of the second dielectric layer 120 being at different horizontal heights, the hard mask layer 90 is formed by a remaining hard mask material during formation of the connectors 80. During formation of the connectors 80, the hard mask material is deposited in both the memory region A and the peripheral region B, grooves are formed in the peripheral region B by means of a patterning process and an etching process so as to separate a plurality of connectors 80, and the memory region A is also synchronously etched to form grooves. Due to the difference in materials, the depth of the grooves formed in the memory region A may be greater than the depth of the grooves in the peripheral region B, and if the depth of the grooves in the memory region A is relatively large, a short circuit may occur to the bit lines 220 due to over-etching. In the embodiments of the present disclosure, by remaining a hard mask material on the surface of a second connector 802, it is possible to prevent the grooves formed by etching in the memory region A from being too deep, thereby avoiding the risk of over-etching, and improving the reliability of devices.

Furthermore, the hard mask layer 90 may be formed by remaining a hard mask material on the top surfaces of the connectors 80 while forming the contact structures 810 and the connectors 80 using a patterning process in the manufacturing process of the semiconductor device, so that additional process steps are not required, thereby achieving the technical effect of improving the performance of the semiconductor device without increasing the process time and process costs.

Hereinafter, the technical solutions in the embodiments of the present disclosure will be clearly and completely described in combination with the accompanying drawings in the embodiments of the present disclosure.

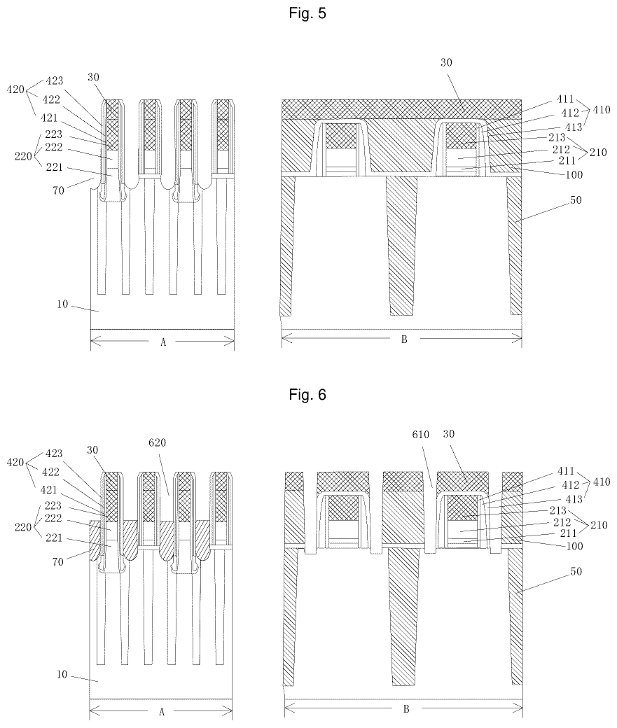

First, as shown in FIG. 5, a substrate 10 is provided, and the substrate 10 includes a cell region and a peripheral region.

The substrate 10 may be a silicon substrate, a silicon-containing substrate, a silicon-on-insulator (SOI) substrate, or other semiconductor substrates, which is not specifically limited in the embodiments of the present disclosure.

In some optional embodiments, shallow trench isolation (STI) structures 50 are formed in the substrate 10, so as to define a plurality of active regions of memory cells in the memory region A of the substrate 10 and define a plurality of active regions of the semiconductor device in the peripheral region B of the substrate 10.

After the substrate 10 is provided, as shown in FIG. 5, a plurality of bit lines 220 are formed on the cell region, a plurality of gate structures 210 are formed on the peripheral region, and a first dielectric layer 100 is formed between adjacent gate structures 210.

In some optional embodiments, as shown in FIG. 5, the plurality of gate structures 210 located on the peripheral region B and the plurality of bit lines 220 located on the memory region A are formed using the same process steps. Exemplarily, a semiconductor material layer, a metal material layer and a hard mask material layer are sequentially formed on the peripheral region B and the memory region A of the substrate 10, and a patterning process is performed on the hard mask material layer to obtain a patterned mask, and then the patterned mask is used as a mask to sequentially etch the metal material layer and the semiconductor material layer, so as to transfer the pattern of the patterned hard mask to the semiconductor material layer, thereby obtaining the gate structures 210 and the bit lines 220.

The gate structures 210 may respectively include a first semiconductor layer 211, a first metal layer 212 and a first patterned mask 213 which are sequentially stacked in a direction away from the substrate 10. The bit lines 220 may respectively include a second semiconductor layer 221, a second metal layer 222 and a second patterned mask 223 which are sequentially stacked in a direction away from the substrate 10. The materials of the first semiconductor layer 211 and the second semiconductor layer 221 may include polysilicon; the materials of the first metal layer 212 and the second metal layer 222 may include aluminum (Al), tungsten (W), copper (Cu), titanium (Ti), titanium aluminum alloy (TiAl) and other low-resistivity metal materials; and the materials of the first patterned mask 213 and the second patterned mask 223 may include any one or more of silicon nitride (SiN), silicon oxynitride (SiON) and silicon carbon nitride (SiCN), and may also include other dielectric materials. The embodiments of the present disclosure do not specifically limit the types of the described materials.

It should be noted that before the step of formation of the gate structures 210, a gate oxide layer (not shown in the figure) may also be formed on the substrate 10, such that the gate oxide layer is located between the substrate 10 and semiconductor portions 22 of the gate structures 210, and the material of the gate oxide layer may be silicon oxide (SiO₂).

After the step of formation of the gate structures 210, as shown in FIG. 5, a first dielectric layer 100 located between adjacent gate structures 210 is formed; and after the step of formation of the first dielectric layer 100, as shown in FIG. 5, the method provided according to embodiments of the present disclosure may further include: a barrier layer 30 located on the gate structures 210 and the first dielectric layer 100 is formed. The materials of the first dielectric layer 100 and the blocking layer 30 may include any one or more of silicon oxide (SiO₂), silicon nitride (SiN), silicon oxynitride (SiON), and silicon carbon nitride (SiCN), and may further include other types of dielectric materials, which are not specifically limited in the embodiments of the present disclosure.

As shown in FIG. 5, the method provided according to embodiments of the present disclosure may further include: a first side wall 410 located at two sides of the gate structure 210 is formed; and a second side wall 420 located at two sides of the bit line 220 is formed.

Exemplarily, the first side wall 410 includes a first insulating layer 411, a second insulating layer 412 and a third insulating layer 413 sequentially covering the side wall of the gate structure 210 from inside to outside; and the second side wall 420 includes a fourth insulating layer 421, a fifth insulating layer 422 and a sixth insulating layer 423 sequentially covering the side walls of the bit line 220 and the barrier layer 30 from inside to outside.

The first side wall 410 and the second side wall 420 may be manufactured using the same process steps, and the materials of the insulating layers in the first side wall 410 and the second side wall 420 may be a conventional insulating material in the related art, such as silicon oxide (SiO₂), which is not specifically limited in the embodiments of the present disclosure.

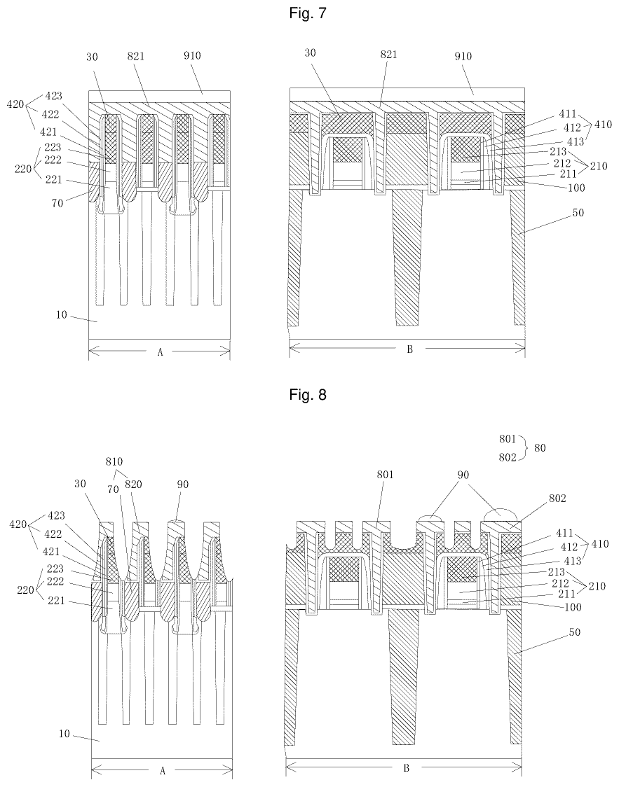

After the step of formation of the first dielectric layer 100, as shown in FIGS. 6 and 7, a plurality of connectors 80 located in the first dielectric layer 100 are formed.

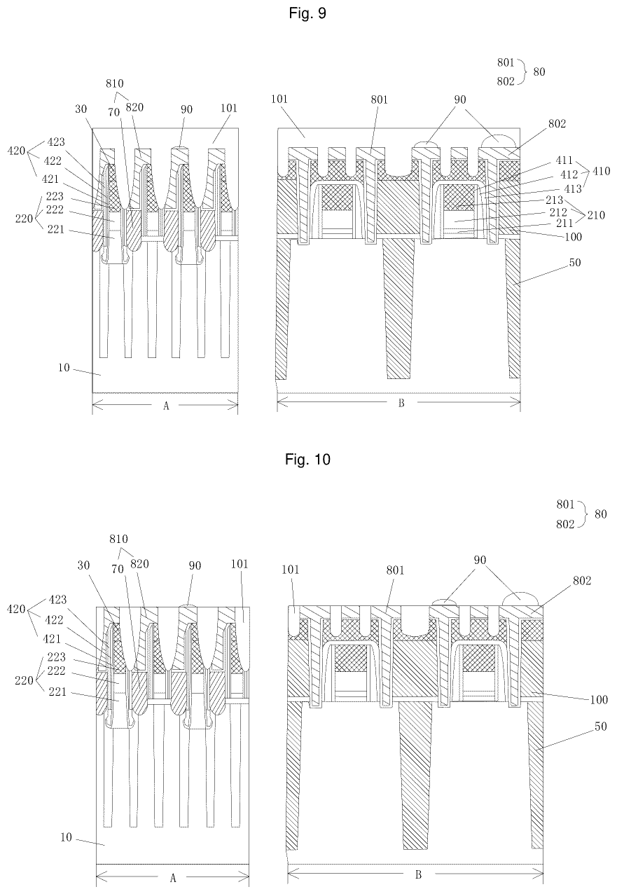

In some optional embodiments, the step of formation of the connectors 80 includes: as shown in FIG. 6, a contact opening 610 is formed on two sides of at least one gate structure 210, the contact opening 610 extending into the substrate 10 from the two sides of the gate structure 210; as shown in FIG. 7, a conductive material 821 is deposited on the substrate 10, such that a part of the conductive material 821 is filled into the contact opening 610 to form the first connecting portion 811 as shown in FIG. 2, and the remaining conductive material 821 forms a conductive layer on one side, facing away from the substrate 10, of the gate electrode structure 210 and the first dielectric layer 100; and as shown in FIGS. 8 and 9, a mask material 910 is deposited on the surface of the conductive layer, the mask material is formed into a patterned mask, and then the conductive layer is etched by means of the patterned mask, so as to form the conductive layer into the second connecting portion 812 as shown in FIG. 2, thereby obtaining the first connector 801 and the second connector 802.

In some embodiments, as shown in FIG. 6, a storage node contact opening 620 located between adjacent bit lines 220 may also be formed while forming the contact opening 610; as shown in FIG. 7, the conductive material 821 may be deposited in both the peripheral region B and the memory region A, and the part of the conductive material 821 deposited in the peripheral region B is filled into the contact opening 610, and the part of the conductive material 821 deposited in the memory region A is filled into the storage node contact opening 620; and as shown in FIG. 8, the mask material 910 deposited on the surface of the conductive layer also covers the surface of the conductive material 821 in the memory region A, and after the mask material is formed into the patterned hard mask, the conductive material 821 is etched by means of the patterned hard mask in the memory region A, so as to form a contact pad 820.

In some optional embodiments, a conductive material covering the bit lines and the gate structures is first formed; a patterned hard mask is formed on the surface of the conductive material; the conductive material is then partially removed to form the connectors and the contact structures; and the patterned hard mask located on the contact structures are then completely removed, so as to form a hard mask layer covering the top surfaces of the connectors.

In some embodiments, while the hard mask material on the top surfaces of the contact structures is completely removed using a patterning process, a part of hard mask material is remained on the top surfaces of the connectors so as to form a hard mask layer, so that it is possible to prevent the grooves formed by etching in the memory region A from being too deep, thereby avoiding the risk of over-etching, and improving the reliability of devices.

In some other optional embodiments, as shown in FIGS. 7 and 8, a conductive material 821 covering the bit lines 220 and the gate structures 210 is formed; a patterned hard mask is formed on the surface of the conductive material 821; the conductive material 821 is partially removed to form the connectors 80 and the contact structures 810; and the patterned hard mask is partially removed to form a first sub-mask covering the connectors 80 and a second sub-mask covering the contact structures 810, the vertex of the first sub-mask being higher than the vertex of the second sub-mask.

In some embodiments, the first sub-mask is disposed on the top surface of at least one connector 80, and the second sub-mask is disposed on the top surface of at least one contact structure 810. The first sub-mask and the second sub-mask may be formed by remaining a hard mask material on the top surfaces of the connectors 80 while forming the contact structures 810 and the connectors 80 using a patterning process in the manufacturing process of the semiconductor device. An etching process is performed after the patterning process, so as to form grooves in the peripheral region B, a plurality of connectors 80 are separated by means of the grooves, and the memory region A is also synchronously etched to form grooves. Due to the difference in materials, the depth of the grooves formed in the memory region A may be greater than the depth of the grooves in the peripheral region B, and if the depth of the grooves in the memory region A is relatively large, a short circuit may occur to the bit lines 220 due to over-etching. The heights of the hard mask material remained on the top surfaces of the connectors 80 are greater than the height of the hard mask material remained on the top surfaces of the contact structures 810, so that it is possible to prevent the grooves formed by etching in the memory region A from being too deep, thereby avoiding the risk of over-etching, and improving the reliability of devices.

After the step of formation of the connectors 80 and the contact structures 810, as shown in FIG. 9, the method provided according to embodiments of the present disclosure may further include: a dielectric material 101 is deposited on the substrate 10, so as to cover the connectors 80, the contact structures 810 and the hard mask layer 90, and is filled between adjacent contact structures 810 and between adjacent connectors 80; and as shown in FIG. 10, the part of the dielectric material 101 covering the connectors 80, the contact structures 810 and the hard mask layer 90 is removed.

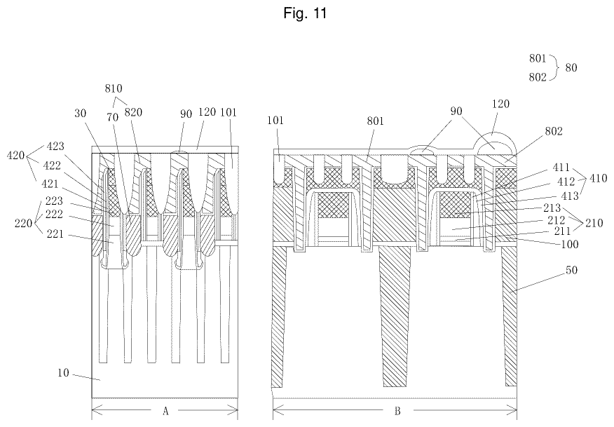

After the step of formation of the dielectric material 101, as shown in FIG. 11, a second dielectric layer 120 is formed. The second dielectric layer 120 includes a first portion located above the hard mask layer 90 and a second portion located above the contact structures 810, and the vertexes of the first portion and the second portion of the second dielectric layer 120 are at different horizontal heights, so that it is possible to prevent the grooves formed by etching in the memory region A from being too deep, thereby avoiding the risk of over-etching, and improving the reliability of devices.

Furthermore, the hard mask layer 90 may be formed by remaining a hard mask material on the top surfaces of the connectors 80 while forming the contact structures 810 and the connectors 80 using a patterning process in the manufacturing process of the semiconductor device, so that additional process steps are not required, thereby achieving the technical effect of improving the performance of the semiconductor device without increasing the process time and process costs.

After the step of formation of the second dielectric layer 120, as shown in FIG. 1, capacitor structures 130 are formed, the capacitor structures 130 being located on the contact structures 810.

It should be further noted that the terms “include”, “including”, or any other variations thereof are intended to cover a non-exclusive inclusion, so that a process, a method, a commodity, or a device that includes a series of elements not only includes those elements, but further includes other elements that are not explicitly listed, or further includes inherent elements of the process, the method, the commodity, or the device. Without further limitation, an element defined by a sentence “include a . . . ” does not exclude other same elements existing in the process, the method, the commodity, or the device that includes the elements.

The content above merely relates to embodiments of the present disclosure and is not intended to limit the embodiments of the present disclosure. For a person skilled in the art, the embodiments of the present disclosure may have various modifications and variations. Any modifications, equivalent replacements, improvements, etc. made within the spirit and principle of the embodiments of the present disclosure shall all belong to the scope of protection of the present disclosure.

What is claimed is:

1. A semiconductor device, comprising:
a substrate, comprising a plurality of bit lines and gate structures;
a first dielectric layer, located between adjacent gate structures;
a plurality of connectors, located in the first dielectric layer and connected to the substrate;
a plurality of contact structures, located between adjacent bit lines;
a plurality of capacitor structures, located on the contact structures;
a hard mask layer, covering the top surfaces of the connectors; and
a second dielectric layer, comprising a first portion located above the hard mask layer and a second portion located above the contact structures, vertexes of the first portion and the second portion of the second dielectric layer being at different horizontal heights.

2. The semiconductor device according to claim 1, wherein the vertex of the first portion of the second dielectric layer is higher than the vertex of the second portion.

3. The semiconductor device according to claim 1, wherein the vertex of the hard mask layer is higher than the vertex of the second portion of the second dielectric layer.

4. The semiconductor device according to claim 1, wherein the hard mask layer comprises a first sub-mask covering the connectors and a second sub-mask covering the contact structures, and the vertex of the first sub-mask is higher than the vertex of the second sub-mask.

5. The semiconductor device according to claim 1, wherein the hard mask layer is completely isolated from the top surfaces of the contact structures.

6. The semiconductor device according to claim 1, further comprising a third dielectric layer located above the gate structures and between adjacent connectors, a vertex of the third dielectric layer being lower than the vertex of the hard mask layer.

7. The semiconductor device according to claim 4, wherein the hard mask layer is directly contact the top surfaces of the connectors and the side walls of the capacitor structures.

8. A semiconductor device, comprising:
a substrate, comprising a plurality of bit lines and gate structures;
a first dielectric layer, located between adjacent gate structures;
a plurality of connectors, located in the first dielectric layer and connected to the substrate;
a plurality of contact structures, located between adjacent bit lines;
a plurality of capacitor structures, located on the contact structures;
a hard mask layer, covering the top surfaces of the connectors; and
a second dielectric layer, covering the hard mask layer and being directly contact the top surfaces of the connectors and the side walls of the capacitor structures.

9. The semiconductor device according to claim 8, wherein the hard mask layer comprises a first sub-mask covering the connectors and a second sub-mask covering the contact structures, and a vertex of the first sub-mask is higher than a vertex of the second sub-mask.

10. The semiconductor device according to claim 8, wherein the hard mask layer is completely isolated from the top surfaces of the contact structures.

11. The semiconductor device according to claim 8, further comprising a third dielectric layer located above the gate structures and between adjacent connectors, a vertex of the third dielectric layer being lower than a vertex of the hard mask layer.

12. The semiconductor device according to claim 9, wherein the hard mask layer is directly contact the top surfaces of the connectors and the side walls of the capacitor structures.

13. A method for manufacturing the semiconductor device, comprising:
providing a substrate, the substrate comprising a plurality of bit lines and gate structures;
forming a first dielectric layer between adjacent gate structures;
forming a plurality of connectors located in the first dielectric layer;
forming a plurality of contact structures located between adjacent bit lines;
forming a hard mask layer covering the top surfaces of the connectors; and
forming a second dielectric layer and capacitor structures, the capacitor structures being located on the contact structures, and the second dielectric layer covering the hard mask layer, wherein the second dielectric layer comprises a first portion located above the hard mask layer and a second portion located above the contact structures, and vertexes of the first portion and the second portion of the second dielectric layer are at different horizontal heights.

14. The method according to claim 13, further comprising:
forming a conductive material covering the bit lines and the gate structures;
forming a patterned hard mask on the surface of the conductive material;
partially removing the conductive material to form the connectors and the contact structures; and
completely removing the patterned hard mask located on the contact structures, forming a hard mask layer covering the top surfaces of the connectors.

15. The method according to claim 13, further comprising:
forming a conductive material covering the bit lines and the gate structures;
forming a patterned hard mask on the surface of the conductive material;
partially removing the conductive material to form the connectors and the contact structures; and
partially removing the patterned hard mask to form a first sub-mask covering the connectors and a second sub-mask covering the contact structures, the vertex of the first sub-mask being higher than the vertex of the second sub-mask.

16. The method according to claim 13, further comprising:
forming a third dielectric layer, such that the third dielectric layer is located above the gate structures and between adjacent connectors.
